(19) United States
(12) Patent Application Publication
(10) Pub. No.: US 2014/0137919 A1
(43) Pub. Date: May 22, 2014

(54) SOLAR CELL AND SOLAR CELL MODULE

(71) Applicant: KABUSHIKI KAISHA TOSHIBA, Tokyo (JP)

(72) Inventors: Hideyuki Nakao, Tokyo (JP); Satoshi Takayama, Kanagawa-ken (JP); Haruhi Oooka, Kanagawa-ken (JP)

(73) Assignee: KABUSHIKI KAISHA TOSHIBA, Tokyo (JP)

(21) Appl. No.: 14/078,902

(22) Filed: Nov. 13, 2013

(30) Foreign Application Priority Data
Nov. 16, 2012 (JP) 2012-252328

(51) Int. Cl. H01L 31/0224; H01L 31/05

(52) U.S. Cl. CPC H01L 31/022433; H01L 31/0508
USPC 136/244; 136/256

(57) ABSTRACT

A solar cell includes a substrate, a lower electrode, a lower intermediate layer, a photoelectric conversion film, and an upper electrode. The lower electrode is provided on the major surface of the substrate and has a side surface crossing the major surface. The lower intermediate layer is provided on the major surface and on the lower electrode. The lower intermediate layer includes an overlapping portion overlapping with the lower electrode and a non-overlapping portion not overlapping with the lower electrode and covering the side surface of the lower electrode when projected onto a plane parallel to the major surface. A resistance value of the non-overlapping portion is lower than a resistance value of the overlapping portion. The photoelectric conversion film is provided on the lower intermediate layer and includes an organic semiconductor. The upper electrode is provided on the photoelectric conversion film.

### CROSS-REFERENCE TO RELATED APPLICATIONS

This application is based upon and claims the benefit of priority from Japanese Patent Application No. 2012-252328, filed on Nov. 16, 2012; the entire contents of which are incorporated herein by reference.

### FIELD

Embodiments described herein relate generally to a solar cell and a solar cell module.

### BACKGROUND

There is a solar cell using an organic semiconductor in which a conductive polymer, fullerene, etc. are combined. For the solar cell using an organic semiconductor, a photoelectric conversion film can be formed by a simple method such as the application method and the printing method. An improvement in photoelectric conversion efficiency is required for the solar cell using an organic semiconductor.

### BRIEF DESCRIPTION OF THE DRAWINGS

FIG. 1 is a schematic cross-sectional view showing a solar cell according to a first embodiment;

FIG. 2 is a schematic cross-sectional view showing the solar cell according to the first embodiment;

FIG. 3 is a graph showing characteristics of the solar cell according to the first embodiment;

FIG. 4A to FIG. 4C are schematic cross-sectional views showing other solar cells according to the first embodiment;

FIG. 5 is a schematic cross-sectional view showing a solar cell according to a second embodiment;

FIG. 6A and FIG. 6B are schematic views showing a solar cell module according to a third embodiment; and

FIG. 7 is a schematic plan view showing a solar electricity generation panel according to the third embodiment.

### DETAILED DESCRIPTION

According to one embodiment, a solar cell includes a substrate, a lower electrode, a lower intermediate layer, a photoelectric conversion film, and an upper electrode. The substrate has a major surface. The lower electrode is provided on the major surface and has a side surface crossing the major surface. The lower intermediate layer is provided on the major surface and on the lower electrode. The lower intermediate layer includes an overlapping portion overlapping with the lower electrode and a non-overlapping portion not overlapping with the lower electrode and covering the side surface of the lower electrode when projected onto a plane parallel to the major surface. A resistance value of the non-overlapping portion in a parallel direction parallel to the major surface is lower than a resistance value of the overlapping portion in the parallel direction. The photoelectric conversion film is provided on the lower intermediate layer and includes an organic semiconductor. The upper electrode is provided on the photoelectric conversion film.

According to another embodiment, a solar cell module includes a substrate and a plurality of solar cells. The substrate has a major surface. The solar cells are provided on the major surface. One of the solar cells includes a first lower electrode, a first lower intermediate layer, a first photoelectric conversion film, and a first upper electrode. The first lower electrode is provided on the major surface and has a first side surface crossing the major surface. The first lower intermediate layer is provided on the major surface and on the first lower electrode. The first lower intermediate layer includes a first overlapping portion overlapping with the first lower electrode and a first non-overlapping portion not overlapping with the first lower electrode and covering the first side surface of the first lower electrode when projected onto a plane parallel to the major surface. A resistance value of the first non-overlapping portion in a parallel direction parallel to the major surface is lower than a resistance value of the first overlapping portion in the parallel direction. The first photoelectric conversion film is provided on the first lower intermediate layer and includes an organic semiconductor. The first upper electrode is provided on the first photoelectric conversion film. One other of the solar cells adjacent to the one solar cell includes a second lower electrode, a second lower intermediate layer, a second photoelectric conversion film, and a second upper electrode. The second lower electrode is provided on the major surface and has a second side surface crossing the major surface. The second lower intermediate layer is provided on the major surface and on the second lower electrode. The second lower intermediate layer includes a second overlapping portion overlapping with the second lower electrode and a second non-overlapping portion not overlapping with the second lower electrode and covering the second side surface of the second lower electrode when projected onto a plane parallel to the major surface. A resistance value in a direction parallel to the major surface of the second non-overlapping portion is lower than a resistance value in a direction parallel to the major surface of the second overlapping portion. The second photoelectric conversion film is provided on the second lower intermediate layer and includes an organic semiconductor. The second upper electrode is provided on the second photoelectric conversion film and is electrically connected to the first lower electrode.

Various embodiments will be described hereinafter with reference to the accompanying drawings.

The drawings are schematic or conceptual; and the relationships between the thickness and width of portions, the proportions of sizes among portions, etc. are not necessarily the same as the actual values thereof. Further, the dimensions and proportions may be illustrated differently among drawings, even for identical portions.

In the specification of this application and the drawings, components similar to those described in regard to a drawing thereinabove are marked with the same reference numerals, and a detailed description is omitted as appropriate.

### First Embodiment

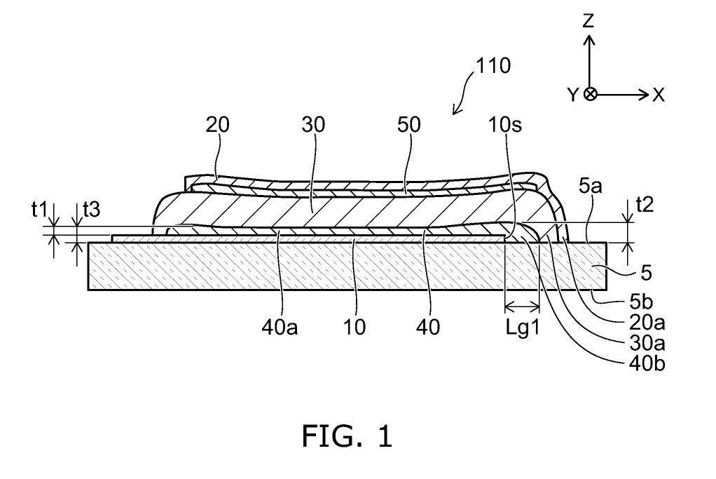

FIG. 1 is a schematic cross-sectional view showing a solar cell according to a first embodiment.

As shown in FIG. 1, a solar cell 110 according to the embodiment includes a substrate 5, a lower electrode 10, an upper electrode 20, a photoelectric conversion film 30, and a lower intermediate layer 40. In this example, the solar cell 110 further includes an upper intermediate layer 50. The solar cell 110 is a photoelectric conversion device that produces a voltage in accordance with the quantity of incident light between the lower electrode 10 and the upper electrode 20. The photoelectric conversion film 30 includes an organic semiconductor. The solar cell 110 is an organic thin film solar cell, for example. The light contributing to the electricity generation of the solar cell 110 is not limited to sunlight. The solar cell 110 generates electricity also by light emitted from a light source such as an electric light bulb, for example.

The substrate 5 has a first major surface 5a (a major surface) and a second major surface 5b. The second major surface 5b is the surface on the opposite side to the first major surface 5a. The lower electrode 10 is provided on the first major surface 5a. The lower electrode 10 has a side surface 10s crossing the first major surface 5a. The lower intermediate layer 40 is provided on the first major surface 5a and on the lower electrode 10. The photoelectric conversion film 30 is provided on the lower intermediate layer 40. The upper electrode 20 is provided on the photoelectric conversion film 30. The upper intermediate layer 50 is provided between the photoelectric conversion film 30 and the upper electrode 20. That is, the upper intermediate layer 50 is provided on the photoelectric conversion film 30, and the upper electrode 20 is provided on the upper intermediate layer 50.

Here, a first direction perpendicular to the first major surface 5a is defined as the Z-axis direction. One direction perpendicular to the Z-axis direction is defined as the X-axis direction. The direction perpendicular to the Z-axis direction and the X-axis direction is defined as the Y-axis direction.

The lower intermediate layer 40 includes an overlapping portion 40a and a non-overlapping portion 40b. The overlapping portion 40a is a portion overlapping with the lower electrode 10 when projected onto a plane parallel to the first major surface 5a (the X-Y plane). The non-overlapping portion 40b is a portion not overlapping with the lower electrode 10 when projected onto the X-Y plane. The non-overlapping portion 40b covers the side surface 10s of the lower electrode 10.

The non-overlapping portion 40b covers the side surface 10s out of the side surfaces of the lower electrode 10. That is, the non-overlapping portion 40b covers at least part of the side surfaces of the lower electrode 10. The non-overlapping portion 40b may cover all the side surfaces of the lower electrode 10. The non-overlapping portion 40b is in a ring shape surrounding the overlapping portion 40a, for example.

Part 30a of the photoelectric conversion film 30 is provided on the first major surface 5a, and covers the non-overlapping portion 40b of the lower intermediate layer 40. The part 30a of the photoelectric conversion film 30 is opposed to the side surface 10s in the X-axis direction, for example. Part 20a of the upper electrode 20 is provided on the first major surface 5a, and covers the part 30a of the photoelectric conversion film 30. The part 20a of the upper electrode 20 is opposed to the side surface 10s in the X-axis direction, for example.

In this example, the substrate 5 and the lower electrode 10 have optical transparency. The substrate 5 and the lower electrode 10 are transparent, for example. The lower electrode 10 is a transparent electrode, for example. In this example, the light that has entered from the second major surface 5b is transmitted through the substrate 5 and the lower electrode 10 and enters the photoelectric conversion film 30. It is also possible to cause light to enter the photoelectric conversion film 30 from the upper electrode 20 side. In this case, the upper electrode 20 is a transparent electrode. Here, the optical transparency is the property of transmitting light of each wavelength that can generate an exciton by being absorbed by the photoelectric conversion film 30, with a transmittance of 70% or more, for example.

The substrate 5, the lower electrode 10, the lower intermediate layer 40, the photoelectric conversion film 30, the upper intermediate layer 50, and the upper electrode 20 extend in the Y-axis direction, for example. The solar cell 110 is in a rectangular shape when projected onto a plane parallel to the first major surface 5a (the X-Y plane) (as viewed in the Z-axis direction), for example.

The substrate 5 supports other components. For the substrate 5, for example, a material that does not substantially alter due to heat, an organic solvent, etc. accompanying the formation of the lower electrode 10 etc. is used. As the material of the substrate 5, for example, an inorganic material such as alkali-free glass and quartz glass is used. The material of the substrate 5 may be a resin material such as polyethylene, polyethylene terephthalate (PET), polyethylene naphthalate (PEN), a polyimide, a polyamide, a polyamide-imide, a liquid crystal polymer, and a cycloolefin polymer or a polymer film, for example. A material having optical transparency is used for the substrate 5. In the case where light is caused to enter from the upper electrode 20 side, a material not having optical transparency may be used for the substrate 5. In this case, the material of the substrate 5 may be a metal substrate of stainless steel (SUS), silicon, or the like, for example. The thickness (the length in the Z-axis direction) of the substrate 5 is not particularly limited. The thickness of the substrate 5 may be any thickness allowing the substrate 5 to have a strength necessary to support other components.

A reflection prevention layer suppressing the reflection of incident light may be provided on the second major surface 5b, between the substrate 5 and the lower electrode 10, or in other positions. As the reflection prevention layer, for example, a reflection prevention coating, a reflection prevention film, a reflection prevention sheet, or the like may be used. As the material of the reflection prevention layer, for example, an inorganic material such as titanium oxide is used. The material of the reflection prevention layer may be an organic material such as an acrylic resin and a polycarbonate resin, for example.

In this example, the lower electrode 10 is a cathode, for example. For the lower electrode 10, a material having optical transparency and electrical conductivity is used. For the lower electrode 10, for example, a conductive metal oxide film, a semitransparent metal thin film, and the like are used. For the metal oxide film, for example, a film fabricated using conductive glass made of indium tin oxide (ITO), fluorine-doped tin oxide (FTO), indium zinc oxide, or the like (NESA etc.) etc. are given. ITO is a compound including indium oxide, zinc oxide, and tin oxide. As the material of the metal thin film, for example, gold, platinum, silver, copper, or the like is given. ITO or FTO is particularly preferable as the material of the lower electrode 10. Also polyaniline, which, is an organic conductive polymer, and a derivative thereof, polythiophene and a derivative thereof, and the like may be used as the material of the lower electrode 10.

In the case where ITO is used for the lower electrode 10, the thickness of the lower electrode 10 is preferably 30 nm to 300 nm. If the thickness is made thinner than 30 nm, electrical conductivity is reduced to increase resistance, and this causes a reduction in photoelectric conversion efficiency. If the thickness is made thicker than 300 nm, the flexibility of ITO is reduced and a crack is likely to occur when stress acts. The sheet resistance of the lower electrode 10 is preferably as low as possible. The sheet resistance of the lower electrode 10 is preferably 10 Ω/square or less, for example.

The lower electrode 10 can be formed by forming the material mentioned above into a film by the vacuum deposition method, the sputtering method, the ion plating method, the plating method, the application method, or the like, for example. The lower electrode 10 may be a single layer or a stacked body in which layers made of materials with different work functions are stacked. In the case where light is caused to enter from the upper electrode 20 side, the material of the lower electrode 10 may not have optical transparency. That is, the material of the lower electrode 10 is not particularly limited as long as it has electrical conductivity.

The lower intermediate layer 40 is a first charge transport layer, for example. In this example, the lower intermediate layer 40 is a hole transport layer. The lower intermediate layer 40 transports holes efficiently and blocks electrons, for example. The lower intermediate layer 40 suppresses the disappearance of excitons generated near the interface of the photoelectric conversion film 30, for example. The lower intermediate layer 40 levels (smoothes) the unevenness of the lower electrode 10 and prevents a short circuit of the solar cell 110, for example.

For the lower intermediate layer 40, for example, an organic conductive polymer such as a polythiophene-based polymer, polyaniline, and polypyrrole is used. As the polythiophene-based polymer, for example, PEDOT/PSS (poly(3,4-ethylenedioxythiophene) poly(styrenesulfonate)) and the like are used. As typical products of the polythiophene-based polymer, for example, Clevios PH500 (registered trademark), CleviosPH, CleviosPV P Al 4083, and CleviosHIL1.1 of H.C. Starck GmbH etc. are given. For inorganic substances, molybdenum oxide is a suitable material. In the case where Clevios PHSO0 is used as the material of the lower intermediate layer 40, the thickness of the overlapping portion 40a of the lower intermediate layer 40 is preferably 20 nm to 100 nm, for example. If the thickness is too thin, the function of preventing a short circuit of the lower electrode 10 is reduced, and a short circuit is likely to occur. If the thickness is too thick, the film resistance is increased to limit the current generated in the photoelectric conversion film 30, and therefore photoelectric conversion efficiency is reduced.

The method for forming the lower intermediate layer 40 is not particularly limited as long as it is a method that can form a thin film. The lower intermediate layer 40 can be applied by the spin coating method or the like, for example. After the material of the lower intermediate layer 40 is applied with a desired thickness, drying by heating is performed using a hot plate or the like. It is preferable to perform drying by heating at 140° C. to 200° C. for approximately several minutes to ten minutes, for example. As the solution to be applied, one filtered beforehand with a filter is preferably used.

The upper intermediate layer 50 is a second charge transport layer, for example. In this example, the upper intermediate layer 50 is an electron transport layer. The upper intermediate layer 50 blocks holes and transports electrons efficiently, for example. The upper intermediate layer 50 suppresses the disappearance of excitons generated near the interface between the photoelectric conversion film 30 and the upper intermediate layer 50, for example. It is also possible to configure the lower intermediate layer 40 as an electron transport layer and the upper intermediate layer 50 as a hole transport layer.

As the material of the upper intermediate layer 50, for example, a metal oxide is used. As the metal oxide, for example, amorphous titanium oxide obtained by hydrolyzing a titanium alkoxide by the sol-gel method and the like are given. The method for film-forming the upper intermediate layer 50 is not particularly limited as long as it is a method that can form a thin film, and the spin coating method is given, for example. In the case where titanium oxide is used as the material of the upper intermediate layer 50, the upper intermediate layer 50 is film-formed preferably with a thickness of 5 nm to 20 nm, for example. If the film thickness is thinner than the range mentioned above, the hole blocking effect is reduced; consequently, generated excitons are deactivated before dissociated into electrons and holes. Thus, it is difficult to extract a current efficiently. If the film thickness is too thick, the film resistance is increased to limit the generated current, and therefore photoelectric conversion efficiency is reduced. As the application solution, one filtered beforehand with a filter is preferably used. After the solution is applied with a prescribed film thickness, drying by heating is performed using a hot plate or the like. The drying by heating is performed in the air at 50° C. to 100° C. for approximately several minutes to ten minutes while hydrolysis is promoted. Metal calcium and the like are suitable materials as inorganic materials.

In this example, the upper electrode 20 is an anode, for example. It is also possible to configure the lower electrode 10 as an anode and the upper electrode 20 as a cathode. In the formation of the upper electrode 20, for example, a material having electrical conductivity is formed into a film by the vacuum deposition method, the sputtering method, the ion plating method, the plating method, the application method, or the like. As the material of the upper electrode 20, for example, a conductive metal thin film, a metal oxide film, or the like is given. In the case where a material with a high work function is used for the lower electrode 10, a material with a low work function is preferably used for the upper electrode 20. As the material with a low work function, for example, an alkali metal, an alkali earth metal, and the like are given. Specifically, at least one of Li, In, Al, Ca, Mg, Sm, Tb, Yb, Zr, Na, K, Rb, Cs, and Ba and an alloy of these may be given. In the case where light is caused to enter the photoelectric conversion film 30 from the upper electrode 20 side, a material having electrical conductivity and optical transparency is used for the upper electrode 20.

The upper electrode 20 may be a single layer or a stacked body in which layers made of materials with different work functions are stacked. The material of the upper electrode 20 may be an alloy of one or more of the materials with a low work function mentioned above and another metal material, for example. As the other metal material added, for example, gold, silver, platinum, copper, manganese, titanium, cobalt, nickel, tungsten, tin, or the like is given. As the alloy, for example, lithium-aluminum alloy, lithium-magnesium alloy, lithium-indium alloy, magnesium-silver alloy, magnesium-indium alloy, magnesium-aluminum alloy, indium-silver alloy, calcium-aluminum alloy, or the like is given.

The thickness of the upper electrode 20 is 10 nm to 300 nm, for example. If the film thickness is thinner than the range mentioned above, the resistance is too large, and it is difficult to transfer the generated charge to an external circuit. If the film thickness is thick, the film formation of the upper electrode 20 takes a long time to increase the temperature of the material, and the photoelectric conversion film 30 (an organic layer) may be damaged and degraded in performance.

Furthermore, since the material is used in a large amount, the occupation time of the film formation apparatus is increased and a cost increase is caused.

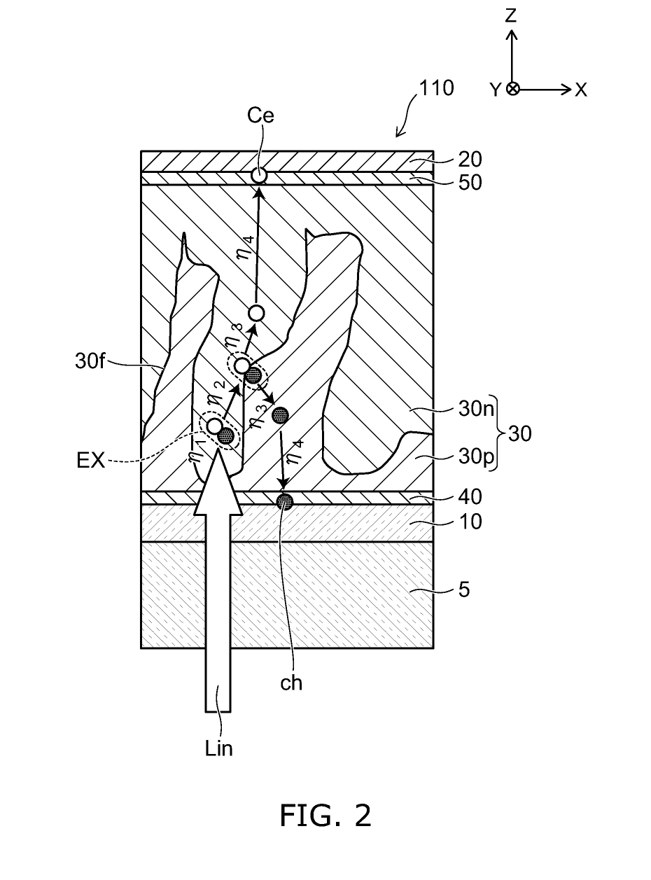

FIG. 2 is a schematic cross-sectional view showing the solar cell according to the first embodiment.

As shown in FIG. 2, the photoelectric conversion film 30 of the solar cell 110 according to the embodiment includes a first semiconductor layer 30n of a first conductivity type and a second semiconductor layer 30p of a second conductivity type. The second semiconductor layer 30p is provided between the lower intermediate layer 40 and the first semiconductor layer 30n. That is, the second semiconductor layer 30p is provided on the lower intermediate layer 40, the first semiconductor layer 30n is provided on the second semiconductor layer 30p, and the upper intermediate layer 50 is provided on the first semiconductor layer 30n. The first conductivity type is the n type and the second conductivity type is the p type, for example. The first conductivity type may be the p type and the second conductivity type may be the n type. In the following, a description is given on the assumption that the first conductivity type is the n type and the second conductivity type is the p type.

The photoelectric conversion film 30 is a thin film of a structure in which the first semiconductor layer 30n and the second semiconductor layer 30p are joined together by bulk heterojunction, for example. The feature of the photoelectric conversion film 30 of a bulk heterojunction type is that the first semiconductor layer 30n (an n-type semiconductor) and the second semiconductor layer 30p (a p-type semiconductor) are blended and a nano-order pn junction spreads through the entire photoelectric conversion film 30. This structure is called a micro-layer separation structure, for example.

In the photoelectric conversion film 30 of a bulk heterojunction type, photocharge separation occurring at the junction surface between the mixed p-type semiconductor and n-type semiconductor is utilized to obtain a current. In the photoelectric conversion film 30 of a bulk heterojunction type, the pn junction region is larger than that in an organic thin film solar cell of the conventional stack type, and the region actually contributing to electricity generation spreads through the entire photoelectric conversion film 30. Therefore, the region contributing to electricity generation in the organic thin film solar cell of a bulk heterojunction type is thicker than that in the organic thin film solar cell of a stack type. Thus, the efficiency of photon absorption is improved, and extractable current is increased.

For the first semiconductor layer 30n, for example, a material having the property of electron accepting is used. For the second semiconductor layer 30p, for example, a material having the property of electron donating is used. In the photoelectric conversion film 30 according to the embodiment, an organic semiconductor is used for at least one of the first semiconductor layer 30n and the second semiconductor layer 30p. The photoelectric conversion film 30 may be of a planar heterojunction type or the like, for example.

In the photoelectric conversion film 30, the first semiconductor layer 30n or the second semiconductor layer 30p absorbs light Lin to generate excitons EX, for example. The generation efficiency is denoted by η1. The generated excitons EX move to the pn junction surface 30f (the junction surface between the first semiconductor layer 30n and the second semiconductor layer 30p) by diffusion. The diffusion efficiency is denoted by η2. Since the exciton has a lifetime, the exciton can move only at approximately the diffusion length. The exciton EX that has reached the pn junction surface 30f is separated into an electron Ce and a hole Ch. The efficiency of the separation of excitons EX is denoted by η3. Holes Ch are transported to the lower electrode 10. Electrons Ce are transported to the upper electrode 20. Thereby, the electrons Ce and the holes Ch (photocarriers) are extracted to the outside. The efficiency of the transportation of photocarriers is denoted by η4.

The efficiency ηEQE of the outward extraction of generated photocarriers to the amount of applied photons can be expressed by the following formula. The value corresponds to the quantum efficiency of the solar cell 110.

ηEQE=η1·η2·η3·η4

An n-type organic semiconductor is used for the first semiconductor layer 30n, for example. A p-type organic semiconductor is used for the second semiconductor layer 30p, for example.

As the p-type organic semiconductor, for example, polythiophene and a derivative thereof, polypyrrole and a derivative thereof, a pyrazoline derivative, an arylamine derivative, a stilbene derivative, a triphenyldiamine derivative, oligothiophene and a derivative thereof, polyvinylcarbazole and a derivative thereof, a polysilane and a derivative thereof, a polysiloxane derivative having an aromatic amine on a side chain or the main chain, polyaniline and a derivative thereof, a phthalocyanine derivative, a porphyrin and a derivative thereof, polyphenylene vinylene and a derivative thereof, polythienylene vinylene and a derivative thereof, or the like may be used. These may be used in combination. A copolymer of these may be used. As the copolymer, for example, a thiophene-fluorene copolymer, a phenylene ethynylene-phenylene vinylene copolymer, and the like are given.

A desirable p-type organic semiconductor is polythiophene, which is a conductive polymer having a n conjugate, and a derivative thereof. Polythiophene and a derivative thereof can ensure excellent stereoregularity and have a relatively high solubility in a solvent. The polythiphene and the derivative thereof are not particularly limited as long as they are a compound having a thiophene skeleton. As specific examples of the polythiophene and the derivative thereof, a polyalkylthiophene, a polyarylthiophene, a polyalkylisothiophene, polyethylenedioxythiophene, and the like are given. As the polyalkylthiphene, for example, poly(3-methylthiophene), poly(3-butylthiophene), poly(3-hexylthiophene), poly(3-octylthiophene), poly(3-decylthiophene), poly(3-dodecylthiophene), and the like are given. As the polyarylthiophene, for example, poly(3-phenylthiophene), a poly(3-p-alkylphenylthiophene), and the like are given. As the polyalkylisothionaphthene, for example, poly(3-butylisothionaphthene), poly(3-hexylisothionaphthene), poly(3-octylisothionaphthene), poly(3-decylisothionaphthene), and the like are given.

These days, a derivative of PCDTBT (poly[N-9″-heptadecanyl-2,7-carbazole-alt-5,5-(4′,T-di-2-thienyl-2′,1′,3′-benzothiadiazole)]), which is a copolymer formed of carbazole, benzothiadiazole, and thiophene, or the like is known as a compound that can provide excellent photoelectric conversion efficiency.

These conductive polymers can be formed into a film by applying a solution in which the polymers are dissolved in a solvent. Thus, there is an advantage that an organic thin film solar cell with a large area can be manufactured at low cost with inexpensive equipment by the printing method or the like.

As the n-type organic semiconductor, fullerene and a derivative thereof are preferably used. Here, the fullerene derivative used is not particularly limited as long as it is a derivative having a fullerene skeleton. Specifically, a derivative formed using C₆₀, C₇₀, C₇₆, C₇₈, C₈₄, and the like as the basic skeleton is given. In the fullerene derivative, carbon atoms in the fullerene skeleton may be modified with arbitrary functional groups, and the functional groups may be bonded together to form a ring. Also a fullerene-bonded polymer is included in the fullerene derivative. The fullerene derivative preferably has a functional group with high affinity with a solvent and has high solubility in a solvent, for example.

As the functional group in the fullerene derivative, for example, a hydrogen atom, a hydroxyl group, a halogen atom, an alkyl group, an alkenyl group, a cyano group, an alkoxy group, an aromatic heterocyclic group, and the like are given. As the halogen atom, for example, a fluorine atom, a chlorine atom, and the like are given. As the alkyl group, for example, a methyl group, an ethyl group, and the like are given. As the alkenyl group, for example, a vinyl group and the like are given. As the alkoxy group, for example, a methoxy group, an ethoxy group, and the like are given. As the aromatic heterocyclic group, for example, an aromatic hydrocarbon group, a thienyl group, a pyridyl group, and the like are given. As the aromatic hydrocarbon group, for example, a phenyl group, a naphthyl group, and the like are given.

More specifically, hydrogenated fullerene, oxide fullerene, a fullerene metal complex, and the like are given. As the hydrogenated fullerene, for example, C₆₀H₃₆, C₇₀H₃₆, and the like are given. As the oxide fullerene, for example, C₆₀, C₇₀, and the like are given.

Among the above, 60PCBM ([6,6]-phenyl-C61-butyric acid methyl ester) or 70PCBM ([6,6]-phenyl-C71-butyric acid methyl ester) are particularly preferably used as the fullerene derivative.

In the case where unmodified fullerene is used, C₇₀ is preferably used. Fullerene C₇₀ has high efficiency of photocarrier generation, and is suitable to be used for an organic thin film solar cell.

In the case where the p-type semiconductor is a P3AT type, the mixing ratio of the n-type organic semiconductor and the p-type organic semiconductor in the photoelectric conversion film 30 is preferably set to approximately n:p=1:1. In the case where the p-type semiconductor is a PCDTBT type, the mixing ratio is preferably set to approximately n:p=4:1.

In order to apply an organic semiconductor, it is necessary to dissolve the organic semiconductor in a solvent. As the solvent used for application, for example, an unsaturated hydrocarbon-based solvent, a halogenated aromatic hydrocarbon-based solvent, a halogenated saturated hydrocarbon-based solvent, an ether, and the like are given. As the unsaturated hydrocarbon-based solvent, for example, toluene, xylene, tetralin, decalin, mesitylene, n-butylbenzene, sec-butylbenzene, tert-butylbenzene, and the like are given. As the halogenated aromatic hydrocarbon-based solvent, for example, chlorobenzene, dichlorobenzene, trichlorobenzene, and the like are given. As the halogenated saturated hydrocarbon-based solvent, for example, carbon tetrachloride, chloroform, dichloromethane, dichloroethane, chlorobutane, bromobutane, chloropentane, chlorohexane, bromohexane, chlorocyclohexane, and the like are given. As the ether, for example, tetrahydrofuran, tetrahydropyran, and the like are given. A halogen-based aromatic solvent is particularly preferable. These solvents may be used singly or in mixture.

As the method for applying a solution to form a film, for example, the spin coating method, the dip coating method, the casting method, the bar coating method, the roll coating method, the wire bar coating method, the spraying method, the screen printing method, the gravure printing method, the flexographic printing method, the offset printing method, gravure offset printing, dispenser application, the nozzle coating method, the capillary coating method, the ink jet method, and the like are given. These application methods may be used singly or in combination.

In this example, the non-overlapping portion 40b of the lower intermediate layer 40 is continuous with the overlapping portion 40a. The material of the non-overlapping portion 40b is substantially the same as the material of the overlapping portion 40a. In this example, the thickness t2 (the length in the Z-axis direction) of the non-overlapping portion 40b is thicker than the thickness t1 of the overlapping portion 40a. Thereby, in the embodiment, the resistance value of the non-overlapping portion 40b in a parallel direction parallel, to the first major surface 5a is made lower than the resistance value of the overlapping portion 40a in the parallel direction. Here, the resistance value in the parallel direction is the sheet resistance in a plane parallel to the first major surface 5a, for example. That is, in the case where the material of the non-overlapping portion 40b is substantially the same as the material of the overlapping portion 40a, making the thickness t2 of the non-overlapping portion 40b thicker than the thickness t1 of the overlapping portion 40a is equivalent to making the resistance value (e.g. the sheet resistance) of the non-overlapping portion 40b lower than the resistance value (e.g. the sheet resistance) of the overlapping portion 40a.

The length Lg1 in the parallel direction of the non-overlapping portion 40b is not less than 1000 times and not more than 5000 times the thickness t1 of the overlapping portion 40a, for example. The length Lg1 is not less than 100 μm and not more than 500 μm, for example. The length Lg1 is the length of the non-overlapping portion 40b in the direction parallel to the first major surface 5a and perpendicular to the side surface 10s, for example. In this example, the length Lg1 is the length of the non-overlapping portion 40b in the X-axis direction.

The thickness t1 of the overlapping portion 40a is the average thickness of the overlapping portion 40a, for example. The variation rate of the thickness of the overlapping portion 40a is ±5% or less to the average thickness, for example. The thickness of the overlapping portion 40a is preferably substantially uniform. The thickness being substantially uniform refers to the absolute value of the difference between the maximum value and the minimum value of the thickness of the overlapping portion 40a being 5 nm or less, for example.

The thickness t2 of the non-overlapping portion 40b is not less than 1.2 times and not more than 3 times the thickness t1 of the overlapping portion 40a, for example. The thickness t2 is thicker than the thickness t3 of the sum of the thickness of the overlapping portion 40a and the thickness of the lower electrode 10. The thickness t2 of the non-overlapping portion 40b is the thickness of the non-overlapping portion 40b in a position of half the length Lg1 of the non-overlapping portion 40b, for example. The thickness t2 is the thickness of the non-overlapping portion 40b in a position apart from the side surface 10s in the X-axis direction by 100 μm, for example. The thickness of the lower intermediate layer 40 can be found by observing a cross section of the solar cell 110 with an electron microscope or the like, for example.

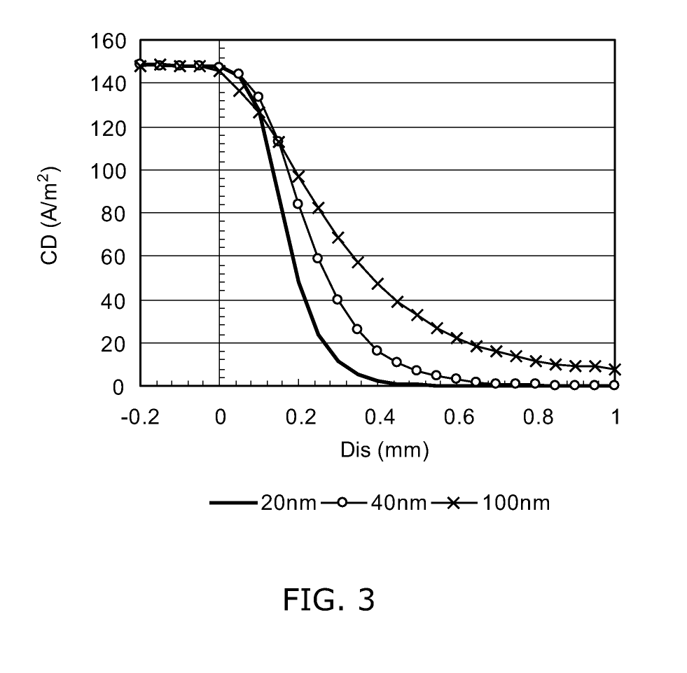

FIG. 3 is a graph showing characteristics of the solar cell according to the first embodiment.

FIG. 3 shows the results of an electrical simulation of the relationship between the distance from the side surface 10s of the lower electrode 10 in the non-overlapping portion 40b and the amount of current flowing through the lower intermediate layer 40 from the position at the distance mentioned above in the non-overlapping portion 40b toward the lower electrode 10. In the simulation, the thickness t2 of the non-overlapping portion 40b is changed and the relationship between the distance and the current is found for each thickness t2.

In the simulation, glass is used as the substrate 5, ITO is used as the lower electrode 10, a PEDOT/PSS film is used as the lower intermediate layer 40, a TiOₓ film is used as the upper intermediate layer 50, and an Al film is used as the upper electrode 20. A p-n bulk heterojunction film is used as the photoelectric conversion film 30. Fullerene of C₇₀ is used as the first semiconductor layer 30n, and a PCDTBT type is used as the second semiconductor layer 30p.

The vertical axis of FIG. 3 is the current density CD (A/m²) of current flowing from the photoelectric conversion film 30 to the lower electrode 10, and the horizontal axis is the distance Dis (mm) from the side surface 10s of the lower electrode 10.

As shown in FIG. 3, it is shown that as the thickness t2 of the non-overlapping portion 40b is made thicker, a current flows to the lower electrode 10 also from positions more distant from the side surface 10s of the lower electrode 10.

The thickness t1 of the overlapping portion 40a of the lower intermediate layer 40 is set so as to be the optimum value with respect to the extraction of current from the photoelectric conversion film 30. If the thickness of the lower intermediate layer 40 is thicker than the optimum value, the maximum value of current extractable from the photoelectric conversion film 30 tends to decrease. However, since the non-overlapping portion 40b protruding from the lower electrode 10 is originally a portion where electricity generation is not expected, it does not matter if the maximum value of extractable current is decreased to a certain degree.

Rather than that, the non-overlapping portion 40b is made thick to reduce the resistance value (e.g. the sheet resistance) in a parallel-to-plane direction (a direction parallel to the X-Y plane), and thus the current generated in a portion outside the lower electrode 10 of the photoelectric conversion film 30 is allowed to pass through the lower intermediate layer 40 to flow to the lower electrode 10 easily. Thereby, the total amount of current extractable from the photoelectric conversion film 30 can be increased as compared to the case where the thickness t2 is the thickness t1 or less. That is, high photoelectric conversion efficiency can be obtained in the solar cell 110 according to the embodiment.

The film thickness configuration of the lower intermediate layer 40 described above is obtained by adjusting the application system, the viscosity of application solution, the drying speed, or the like, for example. An application method called the meniscus method may be used, for example. This application method disposes a component called an applicator near a substrate and holds a small amount of application solution between them. The applicator or the substrate is moved to perform application. In the meniscus method, by changing the setting in application, the film thickness distribution in the end portion of the lower intermediate layer 40 can be adjusted like the embodiment. The setting in application is the amount of application solution, the moving speed of the applicator or the substrate, and the like, for example. Also the drying conditions of the applied solution are important factors, and the film thickness of the non-overlapping portion 40b can be adjusted by adjusting the substrate temperature after application, the air flow around the applied film, and the like, for example. Other than the meniscus method, also in the die coating method, the capillary coating method, and the like, a phenomenon in which the end portion of an applied film is thickened like the embodiment can be obtained by optimizing the setting, for example.

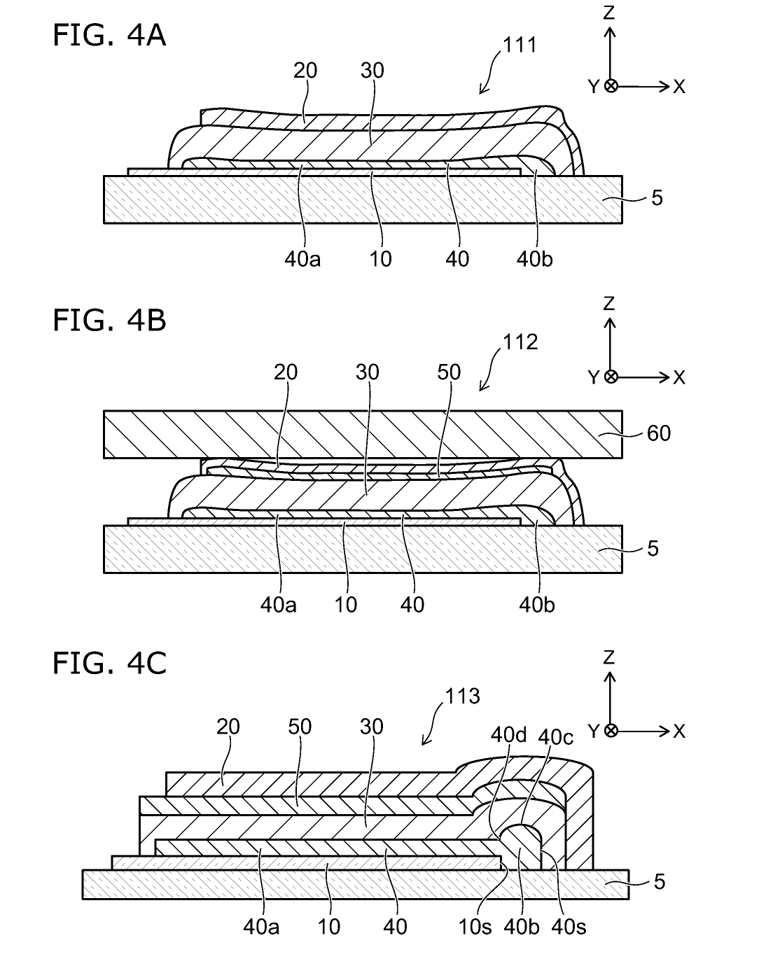

FIG. 4A to FIG. 4C are schematic cross-sectional views showing other solar cells according to the first embodiment.

As shown in FIG. 4A, in a solar cell 111, the upper intermediate layer 50 is omitted. Thus, the upper intermediate layer 50 is appropriately provided as necessary, and may be omitted.

As shown in FIG. 4B, a solar cell 112 further includes a sealing film 60. The sealing film 60 is provided on the upper electrode 20. The sealing film 60 is attached to the upper electrode 20 with a thermosetting epoxy resin, an ultraviolet curable epoxy resin, or the like, for example. The sealing film 60 protects the photoelectric conversion film 30 etc. from oxygen, water, etc., for example. By providing the sealing film 60, the durability of the solar cell 112 can be improved, for example.

As the sealing film 60, for example, a film in which a layer made of an inorganic substance or a metal is provided on the surface of a metal plate or a resin film may be used. As the resin film, for example, a film made of PET, PEN, PI, EVOH, CO, EVA, PC, or PES or a multiple-layer film including two or more of them may be used. As the inorganic substance or the metal, for example, at least one of silica, titania, zirconia, silicon nitride, boron nitride, and Al may be used. A desiccant, an oxygen absorbent, and the like may be further put in the sealing film 60, for example. Thereby, the durability of the solar cell 112 can be further improved, for example.

As shown in FIG. 4C, in a solar cell 113, the portion where the thickness of the non-overlapping portion 40b of the lower intermediate layer 40 is at the maximum is set near the center of the width in the X-axis direction of the non-overlapping portion 40b.

In the solar cell 113, the non-overlapping portion 40a has a central portion 40c and a contact portion 40d. The central portion 40c is the center of the non-overlapping portion 40b in a direction parallel to the major surface 5a and perpendicular to the side surface 10s. The contact portion 40d is a portion in contact with the overlapping portion 40a of the non-overlapping portion 40b. A thickness of the central portion 40c is thicker than a thickness of the contact portion 40d.

In the solar cell 113, the thickness of the portion in contact with the overlapping portion 40a of the non-overlapping portion 40b is substantially the same as the thickness of the sum of the thickness of the overlapping portion 40a and the thickness of the lower electrode 10. The thickness of the overlapping portion 40a is substantially uniform in a direction parallel to the X-Y plane. Thereby, the current generated in a portion outside the lower electrode 10 of the photoelectric conversion film 30 is allowed to flow to the lower electrode 10 easily while the thickness of the overlapping portion 40a is kept at the optimum value. Therefore, in the solar cell 113, photoelectric conversion efficiency can be more enhanced.

### Second Embodiment

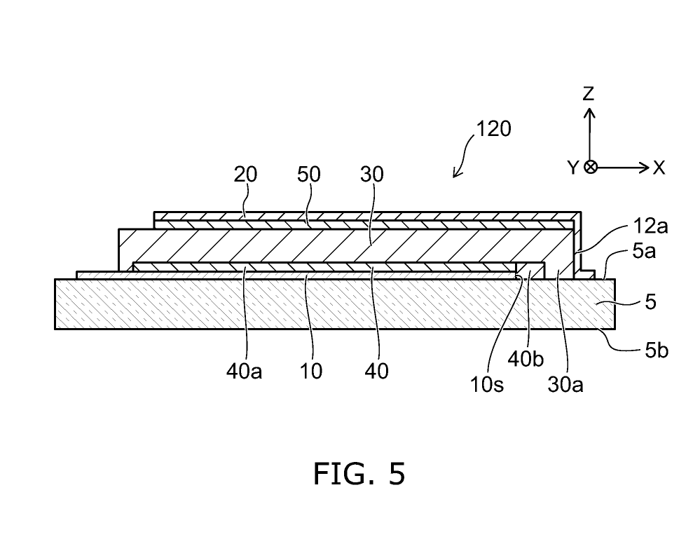

FIG. 5 is a schematic cross-sectional view showing a solar cell according to a second embodiment.

As shown in FIG. 5, the thickness t1 of the non-overlapping portion 40b of the lower intermediate layer 40 of a solar cell 120 is substantially the same as the thickness t3 of the sum of the thickness of the overlapping portion 40a and the thickness of the lower electrode 10. In other words, the absolute value of the difference between the thickness t1 and the thickness t3 is 5 nm or less. In this example, the resistivity of the non-overlapping portion 40b is lower than the resistivity of the overlapping portion 40b. Thereby, in the embodiment, the resistance value (e.g. the sheet resistance) in a direction parallel to the first major surface 5a of the non-overlapping portion 40b is made lower than the resistance value (e.g. the sheet resistance) in a direction parallel to the first major surface 5a of the overlapping portion 40a. That is, making the resistivity of the non-overlapping portion 40b lower than the resistivity of the overlapping portion 40a is equivalent to making the resistance value of the non-overlapping portion 40b lower than the resistance value of the overlapping portion 40a.

A material having a lower resistivity than the overlapping portion 40a is used for the non-overlapping portion 40b, for example. Thereby, the resistivity of the non-overlapping portion 40b can be made lower than the resistivity of the overlapping portion 40b. It is shown by the manufacturer of PEDOT:PSS that the electric conductivity of PEDOT:PSS can be controlled by adding an additive, for example. Through the findings, when PEDOT:PSS is used for the lower intermediate layer 40, the overlapping portion 40a and the non-overlapping portion 40b can be formed by adjusting the amount of additive added, for example.

It is known that the electric conductivity of PEDOT:PSS can be controlled by adding dimethylformamide, ethylene glycol, dimethyl sulfoxide, N-methylpyrrolidone, or the like, for example. The electric conductivity can be raised by approximately two digits by adding ethylene glycol to PEDOT:PSS at a ratio of 5 wt % (percent by mass), for example. In PH500 described above, the electric conductivity when ethylene glycol is not added is approximately 1 S/m (siemens/meter). In contrast, the electric conductivity when 5 wt % ethylene glycol is added is approximately 100 S/m.

The resistivity of the non-overlapping portion 40b is not less than 1/1000 and not more than ⅕ of the resistivity of the overlapping portion 40a, for example. The resistivity of the overlapping portion 40a is not less than 0.5 Ωm and not more than 5 Ωm, for example, and the resistivity of the non-overlapping portion 40b is not less than 10⁻³ Ωm and not more than 0.1 Ωm, for example. Thereby, also in the solar cell 120, the total amount of current extractable from the photoelectric conversion film 30 can be increased, and high photoelectric conversion efficiency can be obtained. The resistivity of the lower intermediate layer 40 can be found by analyzing the material of the lower intermediate layer 40 by SIMS or the like, for example.

In the configuration of the solar cell 120, the thickness t2 of the non-overlapping portion 40b may be made thicker than the thickness t3 of the sum of the thickness of the overlapping portion 40a and the thickness of the lower electrode 10. Thereby, the photoelectric conversion efficiency of the solar cell 120 can be more enhanced.

The formation of the lower intermediate layer 40 in which the material is different between the overlapping portion 40a and the non-overlapping portion 40b can be performed by the meniscus method, but the ink jet method is more suitable.

### Third Embodiment

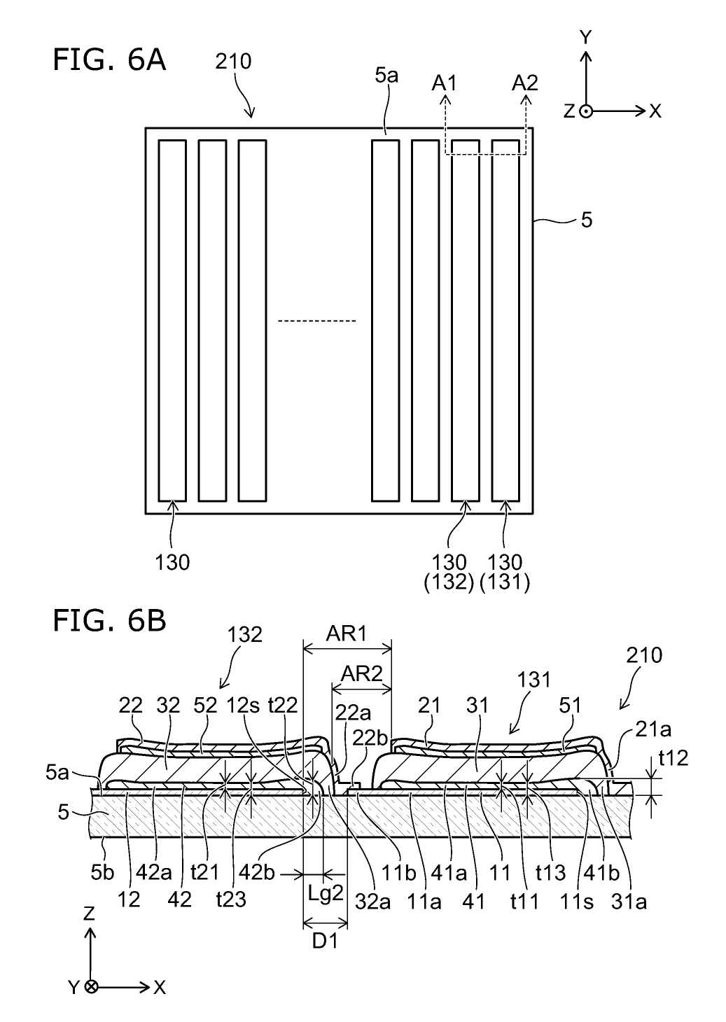

FIG. 6A and FIG. 6B are schematic views showing a solar cell module according to a third embodiment.

FIG. 6A is a schematic plan view showing the solar cell module, and FIG. 6B is a schematic cross-sectional view showing the solar cell module. FIG. 6B schematically shows a cross section taken along line A1-A2 of FIG. 6A.

As shown in FIG. 6A and FIG. 6B, a solar cell module 210 includes the substrate 5 and a plurality of solar cells 130 (what are called cells). The substrate 5 has the first major surface 5a and the second major surface 5b. The second major surface 5b is the surface on the opposite side to the first major surface 5a. The shape of the substrate 5 (the first major surface 5a) projected onto the Z-axis direction is a rectangle, for example.

The plurality of solar cells 130 are provided to be aligned on the first major surface 5a. In this example, the shape of the solar cell 130 projected onto the Z-axis direction is a rectangle extending in the Y-axis direction. In this example, the plurality of solar cells 130 are aligned in the X-axis direction at prescribed intervals. The width in the X-axis direction (the length in the X-axis direction) of the solar cell 130 is approximately 10 mm to 15 mm, for example. The length of one side of the substrate 5 is 30 cm, for example. In this case, approximately 20 solar cells 130 are provided to be aligned in the X-axis direction, for example.

The plurality of solar cells 130 are connected in series, for example. As described in the first embodiment mentioned above, a transparent electrode is used for the solar cell. The resistance value of the material used for the transparent electrode is higher than that of metals and the like. In the solar cell module, a plurality of solar cells are provided, and they are connected in series. Thereby, the increase in the resistance value of the transparent electrode due to an increase in the area of the transparent electrode can be suppressed, for example. In the solar cell module, in the case where a transparent electrode is used for the solar cell, in general approximately 10 to 15 solar cells are connected in series for a substrate with a size of 10 cm to 20 cm.

The shape of the substrate 5 is not limited to a rectangle but may be an arbitrary shape. The configuration and arrangement of the solar cells 130 are not limited to the foregoing. The configuration and arrangement of the solar cells 130 may be appropriately set in accordance with the shape of the substrate 5 etc., for example. The number of solar cells 130 may be an arbitrary number in accordance with the size of the substrate 5 etc., for example. Part of the plurality of solar cells 130 may be connected in parallel. For example, in the case of including 20 solar cells 130, two sets of ten solar cells 130 may each be connected in series and the sets may be connected in parallel. The solar cell module 210 needs only to include at least two solar cells 130 connected in series.

One of the plurality of solar cells 130 is referred to as a first solar cell 131. One other of the plurality of solar cells 130 is referred to as a second solar cell 132. The second solar cell 132 is adjacent to the first solar cell 131.

The first solar cell 131 includes a first lower electrode 11, a first upper electrode 21, a first photoelectric conversion film 31, and a first lower intermediate layer 41. In this example, the first solar cell 131 further includes a first upper intermediate layer 51. The first lower electrode 11 is provided on the first major surface 5a. The first lower electrode 11 has a first side surface 11s crossing the first major surface 5a. The first lower intermediate layer 41 is provided on the first major surface 5a and on the first lower electrode 11. The first photoelectric conversion film 31 is provided on the first lower intermediate layer 41. The first upper electrode 21 is provided on the first photoelectric conversion film 31. The first upper intermediate layer 51 is provided between the first photoelectric conversion film 31 and the first upper electrode 21. The first upper intermediate layer 51 is appropriately provided as necessary, and may be omitted.

The first lower intermediate layer 41 includes a first overlapping portion 41a and a first non-overlapping portion 41b. The first overlapping portion 41a is a portion overlapping with the first lower electrode 11 when projected onto a plane parallel to the first major surface 5a (the X-Y plane). The first non-overlapping portion 41b is a portion not overlapping with the first lower electrode 11 when projected onto the X-Y plane. The first non-overlapping portion 41b covers the first side surface 11s of the first lower electrode 11.

Part 31a of the first photoelectric conversion film 31 is provided on the first major surface 5a, and covers the first non-overlapping portion 41b of the first lower intermediate layer 41. The part 31a of the first photoelectric conversion film 31 is opposed to the first side surface 11s in the X-axis direction, for example. Part 21a of the first upper electrode 21 is provided on the first major surface 5a, and covers the part 31a of the first photoelectric conversion film 31. The part 21a of the first upper electrode 21 is opposed to the first side surface 11s in the X-axis direction, for example.

The first lower electrode 11 has a first portion 11a and a second portion 11b. The second portion 11b is juxtaposed to the first portion 11a in the X-axis direction. The first portion 11a is disposed between the second portion 11b and the first non-overlapping portion 41b in the X-axis direction. The first lower intermediate layer 41 is provided on the first portion 11a. The first portion 11a is a portion of the first lower electrode 11 overlapping with the first lower intermediate layer 41 when projected onto the X-Y plane. The second portion 11b is a portion of the first lower electrode 11 not overlapping with the first lower intermediate layer 41 when projected onto the X-Y plane. The second portion 11b does not overlap with the first photoelectric conversion film 31, the first upper intermediate layer 51, and the first upper electrode 21 either, when projected onto the X-Y plane.

The second solar cell 132 includes a second lower electrode 12, a second upper electrode 22, a second photoelectric conversion film 32, and a second lower intermediate layer 42. In this example, the second solar cell 132 further includes a second upper intermediate layer 52. The second lower electrode 12 is provided on the first major surface 5a. The second lower electrode 12 has a second side surface 12s crossing the first major surface 5a. The second lower intermediate layer 42 is provided on the first major surface 5a and on the second lower electrode 12. The second photoelectric conversion film 32 is provided on the second lower intermediate layer 42. The second upper electrode 22 is provided on the second photoelectric conversion film 32. The second upper intermediate layer 52 is provided between the second photoelectric conversion film 32 and the second upper electrode 22. The second upper intermediate layer 52 is appropriately provided as necessary, and may be omitted.

The second lower intermediate layer 42 includes a second overlapping portion 42a and a second non-overlapping portion 42b. The second overlapping portion 42a is a portion overlapping with the second lower electrode 12 when projected onto a plane parallel to the first major surface 5a (the X-Y plane). The second non-overlapping portion 42b is a portion not overlapping with the second lower electrode 12 when projected onto the X-Y plane. The second non-overlapping portion 42b is disposed between the first lower electrode 11 and the second lower electrode 12. The second non-overlapping portion 42b covers the second side surface 12s of the second lower electrode 12.

Part 32a of the second photoelectric conversion film 32 is provided on the first major surface 5a, and covers the second non-overlapping portion 42b of the second lower intermediate layer 42. The part 32a of the second photoelectric conversion film 32 is opposed to the second side surface 12s in the X-axis direction, for example. Part 22a of the second upper electrode 22 is provided on the first major surface 5a, and covers the part 32a of the second photoelectric conversion film 32. The part 22a of the second upper electrode 22 is opposed to the second side surface 12s in the X-axis direction, for example.

The second upper electrode 22 extends from the part 22a in the X-axis direction, and has an extension portion 22b in contact with the second portion 11b of the first lower electrode 11. The extension portion 22b covers the upper side of the second portion 11b. Thereby, the second upper electrode 22 is electrically connected to the first lower electrode 11. That is, the second solar cell 132 is connected in series to the first solar cell 131.

The thickness t12 of the first non-overlapping portion 41b is thicker than the thickness t11 of the first overlapping portion 41a. The thickness t12 of the first non-overlapping portion 41b is thicker than the thickness t13 of the sum of the thickness of the first overlapping portion 41a and the thickness of the first lower electrode 11. Thereby, the resistance value (e.g. the sheet resistance) of the first non-overlapping portion 41b in the parallel direction is made lower than the resistance value (e.g. the sheet resistance) of the first overlapping portion 41a in the parallel direction.

The thickness t22 of the second non-overlapping portion 42b is thicker than the thickness t21 of the second overlapping portion 42a. The thickness t22 of the second non-overlapping portion 42b is thicker than the thickness t23 of the sum of the thickness of the second overlapping portion 42a and the thickness of the second lower electrode 12. Thereby, the resistance value (e.g. the sheet resistance) of the second non-overlapping portion 42b in the parallel direction is made lower than the resistance value (e.g. the sheet resistance) of the second overlapping portion 42a in the parallel direction.

The configuration of the first solar cell 131 and the second solar cell 132 is substantially the same as the configuration of the solar cell 110 illustrated in the first embodiment mentioned above. The configuration of the first solar cell 131 and the second solar cell 132 may be expressed as a configuration in which two solar cells 110 are disposed side by side and they are connected in series, for example. The function, material, etc. of the components of the first solar cell 131 and the second solar cell 132 may be substantially the same as those of the solar cell 110 described in regard to the first embodiment. Thus, a detailed description of them is omitted.

The distance D1 in the X-axis direction between the first lower electrode 11 and the second lower electrode 12 is 600 μm (not less than 400 μm and not more than 1000 μm), for example. The length Lg2 in the X-axis direction of the second non-overlapping portion 42b is not less than 100 μm and not more than 500 μm, for example. The length Lg2 is set to half the distance D1, for example. The thickness t22 of the second non-overlapping portion 42b is the thickness of the second non-overlapping portion 42b in a position of half the length Lg2 of the second non-overlapping portion 42b, for example. The thickness t22 is the thickness of the second non-overlapping portion 42b in a position apart from the second side surface 12s in the X-axis direction by a length of ¼ of the distance D1, for example. The thickness t22 is the thickness of the second non-overlapping portion 42b in a position apart from the second side surface 12s in the X-axis direction by 100 μm, for example.

The plurality of solar cells 130 are connected in series. In the plurality of solar cells 130, the configuration of the portion connected in series is the configuration described in regard to the first solar cell 131 and the second solar cell 132.

A solar cell module using an organic thin film solar cell is lower than a solar cell module using a solar cell including an inorganic material such as CIGS and a-Si in its photoelectric conversion film. One of the causes of reducing the photoelectric conversion efficiency of the solar cell module using an organic thin film solar cell is the open area ratio. The open area ratio is the ratio of the area of the portion contributing to electricity generation to the area of the module. When a plurality of solar cells are connected in series, it is necessary to draw an interconnection from the lower electrode provided immediately above a substrate to the uppermost upper electrode. Since a space for drawing the interconnection is provided, the region not contributing to electricity generation in the solar cell module is increased. The open area ratio of the solar cell module is reduced.

In a solar cell module using an inorganic-based solar cell, the path of the interconnection is formed by a technique called scribing (groove processing). However, in an organic thin film solar cell, the conventional scribing technique is not effective due to the difference in the light absorption properties, the rigidity, etc. of the material. In particular, in the case where an organic polymer material is used, the application of scribing technique is difficult. Therefore, in the case where a plurality of solar cells using an organic polymer material are connected in series, each layer is film-formed in a state where each solar cell is separated.

In the case of using an organic polymer material, the organic material is dissolved in a solvent and the solution is formed into a film by application technique. This method has the advantage that the initial cost can be suppressed in terms of a vacuum apparatus not being needed, as compared to film formation by vapor deposition and sputtering. On the other hand, the pattern accuracy of application technique is lower than that of vapor deposition and the like. Therefore, when each solar cell is film-formed separately, the spacing between solar cells is widened. As a result, the open area ratio of the solar cell module using an organic thin film solar cell is lower than the open area ratio of the solar cell module using an inorganic-based solar cell.

In the solar cell module 210 according to the embodiment, by making the resistance value of the first non-overlapping portion 41b and the second non-overlapping portion 42b low, also the portions protruding from the first lower electrode 11 and the second lower electrode 12 are made to contribute to electricity generation. Thereby, in the solar cell module 210, the effective open area ratio can be increased. In the solar cell module 210, the total amount of current extractable from the first photoelectric conversion film 31 and the second photoelectric conversion film 32 can be increased and high photoelectric conversion efficiency can be obtained.

In the case where, for example, the resistance value of the first non-overlapping portion 41b is substantially the same as or higher than the resistance value of the first overlapping portion 41a, the portion contributing to electricity generation of the first solar cell 131 is the portion where the first lower electrode 11 and the first upper electrode 21 are opposed in the Z-axis direction. In this case, the region not contributing to electricity generation between the first solar cell 131 and the second solar cell 132 is AR1.

In contrast, in the solar cell module 210 according to the embodiment, the region not contributing to electricity generation between the first solar cell 131 and the second solar cell 132 can be made AR2. Thus, in the solar cell module 210, the effective open area ratio can be increased and high photoelectric conversion efficiency can be obtained.

The configuration of the first solar cell 131 and the second solar cell 132 may be substantially the same as that of the solar cell 111, the solar cell 112, the solar cell 113, or the solar cell 120 illustrated in the embodiments mentioned above, for example.

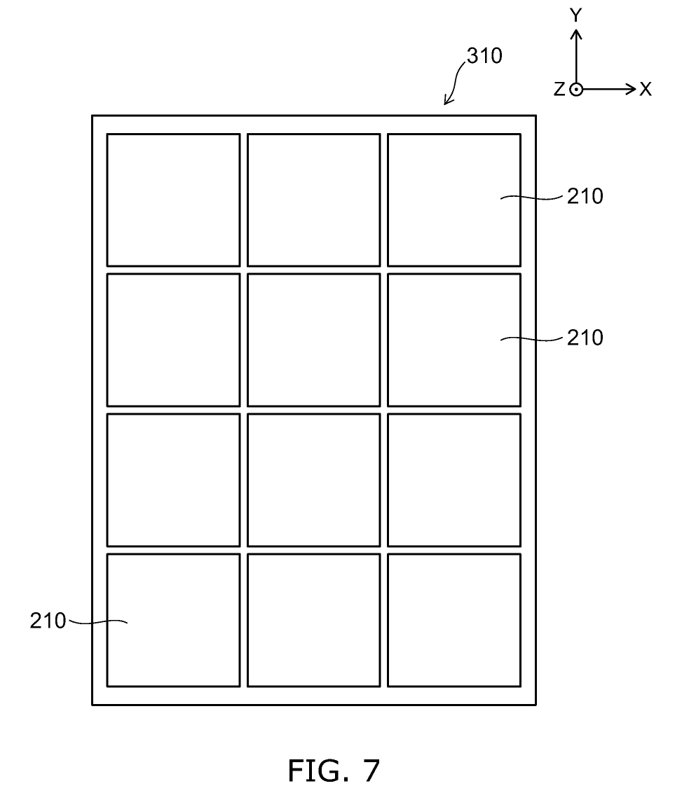

FIG. 7 is a schematic plan view showing a solar electricity generation panel according to the third embodiment.

As shown in FIG. 7, a solar electricity generation panel 310 includes a plurality of solar cell modules 210. In this example, the solar electricity generation panel 310 includes twelve solar cell modules 210 that are arranged in threes in the X-axis direction and in fours in the Y-axis direction. The length of one side of the solar cell module 210 is approximately 30 cm. The size of the solar electricity generation panel 310 is approximately 1 m×1.2 m, for example. The plurality of solar cell modules 210 are connected in series or in parallel. Thereby, the solar electricity generation panel 310 outputs a prescribed voltage and a prescribed current. Thus, the solar cell module 210 may be used as the solar electricity generation panel 310 in which a plurality of solar cell modules 210 are electrically connected. The number and arrangement of solar cell modules 210 included in the solar electricity generation panel 310 may be set arbitrarily.

In the above, the case is described where the lower intermediate layers 40 to 42 are hole transport layers and the upper intermediate layers 50 to 52 are electron transport layers. However, the case is possible where the lower intermediate layers 40 to 42 are electron transport layers and the upper intermediate layers 50 to 52 are hole transport layers. For example, there is a configuration called an inverse structure. In the inverse structure, the lower electrodes 10 to 12 (transparent electrodes) are anodes and the upper electrodes 20 to 22 (counter electrodes) are cathodes. This case has a configuration in which the lower electrodes 10 to 12, which are anodes, the lower intermediate layers 40 to 42, which are electron transport layers, the photoelectric conversion films 30 to 32, the upper intermediate layers 50 to 52, which are hole transport layers, and the upper electrodes 20 to 22, which are cathodes, are arranged in this order from the substrate 5 side. Also in this case, by reducing the resistance value of the non-overlapping portions 40b to 42b of the lower intermediate layers 40 to 42, high photoelectric conversion efficiency can be obtained. In the case of the solar cell module, the effective open area ratio can be increased.

The embodiment provides a solar cell and a solar cell module with high photoelectric conversion efficiency.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel. In the specification of this application, the state of being “provided on” includes not only the state of being provided in direct contact but also the state of being provided via another component. The state of being “stacked” includes not only the state of being stacked in contact with each other but also the state of being stacked via another component. The state of being “opposed” includes not only the state of facing directly but also the state of facing via another component.

Hereinabove, embodiments of the invention are described with reference to specific examples.

However, the embodiment of the invention is not limited to these specific examples. For example, one skilled in the art may appropriately select specific configurations of components of solar cells and solar cell modules such as substrates, lower electrodes, lower intermediate layers, photoelectric conversion films, upper electrodes, upper intermediate layers, first lower electrodes, first lower intermediate layers, first photoelectric conversion films, first upper electrodes, second lower electrodes, second lower intermediate layers, second photoelectric conversion films, and second upper electrodes from known art and similarly practice the invention. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all solar cells and solar cell modules practicable by an appropriate design modification by one skilled in the art based on the solar cells and solar cell modules described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A solar cell comprising:
a substrate having a major surface;
a lower electrode provided on the major surface and having a side surface crossing the major surface;
a lower intermediate layer provided on the major surface and on the lower electrode, the lower intermediate layer including an overlapping portion overlapping with the lower electrode and a non-overlapping portion not overlapping with the lower electrode and covering the side surface of the lower electrode when projected onto a plane parallel to the major surface, a resistance value of the non-overlapping portion in a parallel direction parallel to the major surface being lower than a resistance value of the overlapping portion in the parallel direction;
a photoelectric conversion film provided on the lower intermediate layer and including an organic semiconductor; and
an upper electrode provided on the photoelectric conversion film.

2. The solar cell according to claim 1, wherein a thickness in a first direction perpendicular to the major surface of the non-overlapping portion is thicker than a thickness in the first direction of the overlapping portion.

3. The solar cell according to claim 2, wherein the thickness of the non-overlapping portion is thicker than a thickness of a sum of the thickness of the overlapping portion and a thickness in the first direction of the lower electrode.

4. The solar cell according to claim 1, further comprising an upper intermediate layer provided between the photoelectric conversion film and the upper electrode.

5. The solar cell according to claim 4, wherein
the lower intermediate layer is a first charge transport layer and
the upper intermediate layer is a second charge transport layer.

6. The solar cell according to claim 1, wherein the substrate and the lower electrode have optical transparency.

7. The solar cell according to claim 1, wherein the photoelectric conversion film includes:
a first semiconductor layer of a first conductivity type; and
a second semiconductor layer of a second conductivity type provided between the lower intermediate layer and the first semiconductor layer.

8. The solar, cell according to claim 7, wherein the first semiconductor layer is joined to the second semiconductor layer by bulk heterojunction.

9. The solar cell according to claim 8, wherein
the first semiconductor layer includes an n-type organic semiconductor and
the second semiconductor layer includes a p-type organic semiconductor.

10. The solar cell according to claim 1, wherein the non-overlapping portion is continuous with the overlapping portion.

11. The solar cell according to claim 1, wherein a length in a direction parallel to the major surface and perpendicular to the side surface of the non-overlapping portion is not less than 1000 times and not more than 5000 times a thickness of the overlapping portion.

12. The solar cell according to claim 1, wherein a thickness of the non-overlapping portion is not less than 1.2 times and not more than 3 times a thickness of the overlapping portion.

13. The solar cell according to claim 1, further comprising a sealing film provided on the upper electrode.

14. The solar cell according to claim 1, wherein
the non-overlapping portion has a central portion and a contact portion,
the central portion is the center of the non-overlapping portion in a direction parallel to the major surface and perpendicular to the side surface,
the contact portion is a portion in contact with the overlapping portion of the non-overlapping portion, and
a thickness of the central portion is thicker than a thickness of the contact portion.

15. The solar cell according to claim 1, wherein a resistivity of the non-overlapping portion is lower than a resistivity of the overlapping portion.

16. The solar cell according to claim 15, wherein an absolute value of a difference between a thickness of the non-overlapping portion and a thickness of a sum of a thickness of the overlapping portion and a thickness of the lower electrode is 5 nm or less.

17. The solar cell according to claim 15, wherein a material of the non-overlapping portion is different from a material of the overlapping portion.

18. The solar cell according to claim 15, wherein a resistivity of the non-overlapping portion is not less than 1/1000 and not more than ⅕ of a resistivity of the overlapping portion.

19. The solar cell according to claim 15, wherein a thickness of the non-overlapping portion is thicker than a thickness of a sum of a thickness of the overlapping portion and a thickness of the lower electrode.

20. A solar cell module comprising:
a substrate having a major surface; and
a plurality of solar cells provided on the major surface,
one of the solar cells including:
a first lower electrode provided on the major surface and having a first side surface crossing the major surface;
a first lower intermediate layer provided on the major surface and on the first lower electrode, the first lower intermediate layer including a first overlapping portion overlapping with the first lower electrode and a first non-overlapping portion not overlapping with the first lower electrode and covering the first side surface of the first lower electrode when projected onto a plane parallel to the major surface, a resistance value of the first non-overlapping portion in a parallel direction parallel to the major surface being lower than a resistance value of the first overlapping portion in the parallel direction parallel to the major surface of the first overlapping portion;
a first photoelectric conversion film provided on the first lower intermediate layer and including an organic semiconductor; and
a first upper electrode provided on the first photoelectric conversion film,
one other of the cells adjacent to the one solar cell including:
a second lower electrode provided on the major surface and having a second side surface crossing the major surface;
a second lower intermediate layer provided on the major surface and on the second lower electrode, the second lower intermediate layer including a second overlapping portion overlapping with the second lower electrode and a second non-overlapping portion not overlapping with the second lower electrode and covering the second side surface of the second lower electrode when projected onto a plane parallel to the major surface, a resistance value of the second non-overlapping portion in a parallel direction parallel to the major surface being lower than a resistance value of the second overlapping portion in the parallel direction;
a second photoelectric conversion film provided on the second lower intermediate layer and including an organic semiconductor; and
a second upper electrode provided on the second photoelectric conversion film and electrically connected to the first lower electrode.
